(19) United States
(12) Patent Application Publication
(10) Pub. No.: US 2012/0056208 A1
(43) Pub. Date: Mar. 8, 2012

(54) SYSTEM FOR DISPLAYING IMAGES

(75) Inventors: Ryuji NISHIKAWA, Hsinchu City (TW); Hsiang-Lun HSU, Miaoli City (TW)

(73) Assignee: CHIMEI INNOLUX CORPORATION, Chu-Nan (TW)

(21) Appl. No.: 13/082,292

(22) Filed: Apr. 7, 2011

Related U.S. Application Data
(60) Provisional application No. 61/379,683, filed on Sep. 2, 2010.

(30) Foreign Application Priority Data
Feb. 23, 2011 (TW) 100105946

(51) Int. Cl. H01L 51/52

(52) U.S. Cl. 257/88; 257/E51.018

(57) ABSTRACT

A system for displaying images includes an organic light-emitting device (OLED) including an anode layer on a substrate, a cathode layer, and an organic light-emitting layer disposed between the anode and cathode layers. The cathode layer includes a metal layer in direct contact with the organic light-emitting layer, a transparent conductive layer, and an organic buffer layer with a carrier mobility in a range of 10⁻³ cm²/(V·s) to 10⁻⁵ cm²/(V·s) disposed between the metal layer and the transparent conductive layer.

### CROSS REFERENCE TO RELATED APPLICATIONS

This application claims the benefit of U.S. Provisional Application No. 61/379,683, filed Sep. 2, 2010, the entirety of which is incorporated by reference herein, and this application claims priority of Taiwan Patent Application No., 100105946, filed on Feb. 23, 2011, the entirety of which is incorporated by reference herein.

### BACKGROUND OF THE INVENTION

1. Field of the Invention

The invention relates to a flat panel display (FPD), and in particular to an organic light-emitting/electroluminescent device (OLED/OELD).

2. Description of the Related Art

Recently, with the development and wide application of electronic products such as mobile phones, PDAs, and notebook computers, there has been increasing demand for flat panel displays (FPDs) which consume less electric power and occupy less space. Organic electroluminescent/light-emitting devices (OELDs/OLEDs) are self-emitting and highly luminous, with a wider viewing angle, a faster response speed, and a simple fabrication process, making them an industry display of choice.

FIG. 1 illustrates a cross section view of a typical organic light-emitting device (OLED) 20. The OLED 20 includes an anode layer 12 formed on a substrate 10, a cathode layer 16 formed over the anode layer 12 and an organic material layer 14 disposed between the anode layer 12 and the cathode layer 14. The organic material layer 14 is typically formed of a stack (not shown) of a hole injecting layer (HIL), a hole transporting layer (HTL), an electroluminescent layer (EML), an electron transporting layer (ETL), and an electron injecting layer (EIL). Moreover, the cathode layer 16 may include a thin metal layer and an overlying transparent conductive layer (not shown). The transparent conductive layer, such as indium tin oxide (ITO), is generally formed by a sputtering process.

The organic material layer 14 under the transparent conductive layer, however, is easily damaged by plasma formed in the sputtering process, thereby deteriorating the light-emitting characteristics. Moreover, oxygen introduced in the sputtering process for formation of the transparent conductive layer (e.g., ITO) may cause the thin metal layer to oxidize, and thus the electron injection ability would also deteriorate.

Accordingly, there exists a need in the art for development of a novel OLED structure, which is capable of mitigating the deficiencies mentioned above.

### BRIEF SUMMARY OF THE INVENTION

A detailed description is given in the following embodiments with reference to the accompanying drawings. An exemplary embodiment of a system for displaying images comprises an organic light-emitting device (OLED) comprising an anode layer on a substrate, a cathode layer, and an organic light-emitting layer disposed between the anode and cathode layers. The cathode layer comprises a metal layer in direct contact with the organic light-emitting layer, a transparent conductive layer, and an organic buffer layer with a carrier mobility in a range of 10⁻³ cm²/(V·s) to 10⁻⁵ cm²/(V·s) disposed between the metal layer and the transparent conductive layer.

### BRIEF DESCRIPTION OF DRAWINGS

The invention can be more fully understood by reading the subsequent detailed description and examples with references made to the accompanying drawings, wherein:

FIG. 1 is a cross section view of a typical OLED;

FIG. 2 is a cross section view of an exemplary embodiment of a system for displaying images, including an OLED, according to the invention;

FIG. 3 is a flow chart of a method for fabrication of the OLED shown in FIG. 2;

FIG. 4 is a diagram showing a relationship between efficiency (cd/A) and current density (mA/cm²);

FIG. 5 is a diagram showing a relationship between luminance (cd/m²) and driving voltage (V);

FIG. 6 is a diagram showing a relationship between current density (mA/cm²) and driving voltage (V);

FIG. 7 is a spectrum diagram of an OLED according to the invention; and

FIG. 8 schematically shows another embodiment of a system for displaying images.

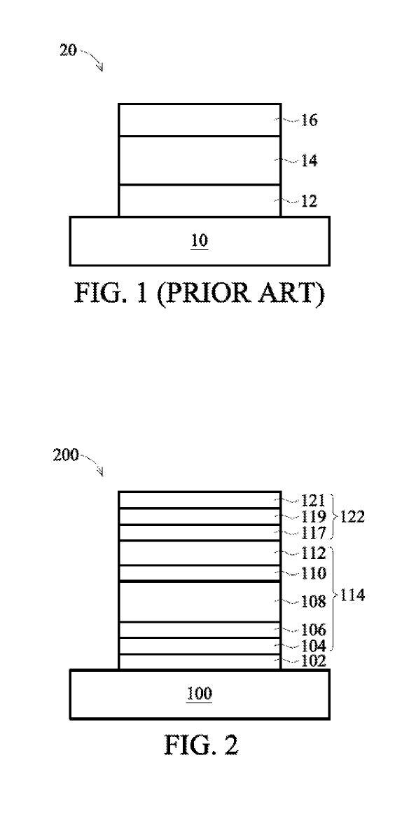

### DETAILED DESCRIPTION OF DISCLOSURE

The following description is of the best-contemplated mode of carrying out the invention. This description is provided for the purpose of illustrating the general principles of the invention and should not be taken in a limiting sense. The scope of the invention is best determined by reference to the appended claims.

Systems for displaying images are provided. FIG. 2 illustrates an embodiment of a system for displaying images according to the disclosure, and in particular to a system for displaying images, including an organic light-emitting device (OLED) 200. In the embodiment, the OLED 200 includes an anode layer 102, a cathode layer 122, and an organic light-emitting layer 114 disposed between the anode layer 102 and the cathode layer 122.

The anode layer 102, such as an ITO or indium zinc oxide (IZO) layer, is disposed on a substrate 100. The substrate 100 may include glass, quartz or other transparent materials. In some embodiments, the substrate 100 may include an opaque material.

The organic light-emitting layer 114 may include a stack of a hole injecting layer (HIL) 104, a hole transporting layer (HTL) 106, an electroluminescent layer (EML) 108, an electron transporting layer (ETL) 110, and an electron injecting layer (EIL) 112.

The cathode layer 122 may include a metal layer 117, an organic buffer layer 119, and a transparent conductive layer 121. The metal layer 117 directly contacts the organic light-emitting layer 114, the transparent conductive layer 121 is disposed over the metal layer 117, and the organic buffer layer 119 is disposed between the metal layer 117 and the transparent conductive layer 121. In the embodiment, the organic buffer layer 119 is used as a protective layer for the underlying organic light-emitting layer 114 during formation of the transparent conductive layer 121, and prevents the underlying metal layer 117 from being oxidized.

Particularly, in order to enhance the carrier injection ability, the organic buffer layer 119 has a carrier mobility, such as an electron mobility, in a range of 10⁻³ cm²/(V·s) to 10⁻⁵ cm²/(V·s). Moreover, the organic buffer layer 119 has a lowest unoccupied molecular orbital (LUMO) in a range of 3.5 eV to 6.5 eV. Additionally, the organic buffer layer 119 has a glass transition temperature of not less than 110° C., thereby preventing the organic buffer layer 119 from being damaged during the formation of the transparent conductive layer 121 at high temperatures.

Note that undesired particles (not shown) may be formed during the formation of the anode layer 102 and the organic light-emitting layer 114, thereby reducing the step coverage of the transparent conductive layer 121 and resulting in cracks formed in the transparent conductive layer 121, and thus if formed, the reliability of the OLED 200 would be reduced. Accordingly, the organic buffer layer 119 disposed between the transparent conductive layer 121 and the metal layer 117 can effectively enhance the step coverage of the transparent conductive layer 121, thereby increasing the reliability of the OLED 200.

Note that if the thickness of the organic buffer layer 119 is too thin, the organic buffer layer 119 would not be able to protect the underlying organic light-emitting layer 114 during the formation of the transparent conductive layer 121. Conversely, if the organic buffer layer 119 is too thick, the driving voltage of the OLED 200 may be increased and color shift may occur. Accordingly, in the embodiment, the organic buffer layer 119 has a thickness in a range of 10 Å to 500 Å, and is preferable in a range of 50 Å to 300 Å. Moreover, in order to maintain the light-emitting characteristics of the OLED 200, the organic buffer layer 119 has a transmittance of not less than 70% and a reflectivity in a range of 1.5 to 2.0.

In one embodiment, the organic buffer layer 119 may comprise hexaazatriphenylene hexacarbonitrile (HAT-CN). In another embodiment, the organic buffer layer 119 may further comprise another organic material, such as bis(10-hydroxybenzo [h] quinolinato)beryllium (BeBq₂).

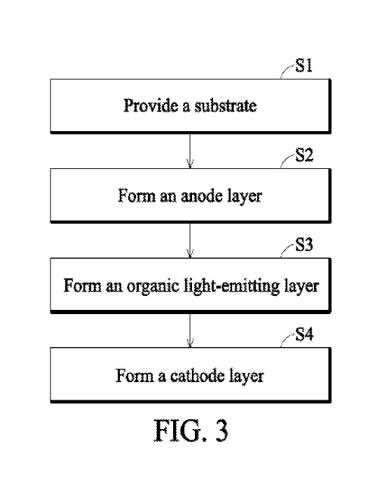

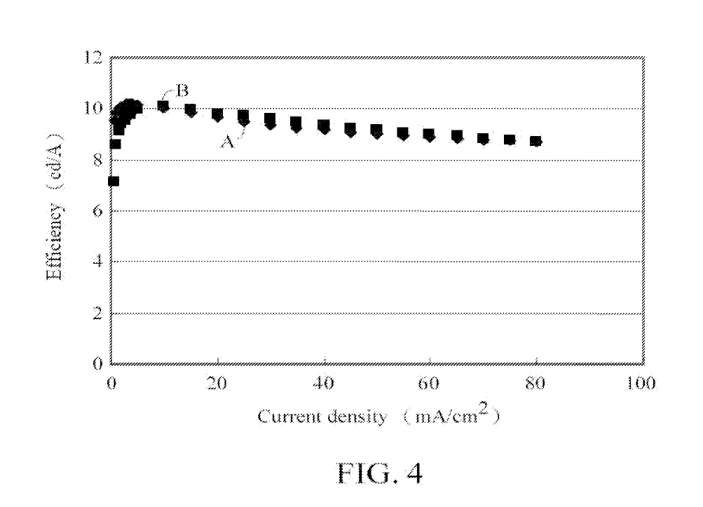

Referring to FIG. 3, which is a flow chart of a method for fabrication of the OLED 200 shown in FIG. 2. First, in the step S1, a substrate 100, such as a glass substrate, is provided. Next, in the step S2, a transparent conductive layer, such as an ITO layer formed by a sputtering process, is deposited on the substrate 100 and has a thickness in a range of 700 Å to 1100 Å to serve as an anode layer 102. Next, the anode layer 102 on the substrate 100 is cleaned using an organic solvent and water. Thereafter, a dry treatment may be performed on the anode layer 102 in an oven at a process temperature in a range of 120° C. to 150° C. Additionally, a UV-ozone treatment is performed on the anode layer 102.

Next, in the step S3, an organic light-emitting layer 114 is formed on the anode layer 102. In the embodiment, the organic light-emitting layer 114 may be formed by thermal evaporation. The organic light-emitting layer 114 may comprise a stack of a hole injecting layer (HIL) 104, a hole transporting layer (HTL) 106, an electroluminescent layer (EML) 108, an electron transporting layer (ETL) 110, and an electron injecting layer (EIL) 112.

In one embodiment, the HIL 104 has a thickness of 600 Å and may include 4,4′,4″-tris(N-3-methylphenyl-N-phenyl-amino)-triphenylamine (m-TDATA). The HTL 106 has a thickness of 200 Å and may include 4,4′-bis[N-(1-naphthyl)-N-phenylamino]biphenyl (α-NPD). The EML 108 may have a multi-layer structure and include a red host material (containing 0.5% red dopant) with a thickness of about 50 Å, a carrier transporting material (e.g., α-NPD) with a thickness of about 50 Å, a green host material (containing 10% green dopant) with a thickness of about 200 Å, and a blue host material (containing 7.5% blue dopant) with a thickness of about 200 Å. In order to simplify the diagram, only a single flat layer is depicted in FIG. 2. ETL 110 has a thickness of about 10 nm and may include BeBq₂. EIL 112 has a thickness of about 400 Å and may include ET 152 (which is fabricated by Idemitsu Kosan Co.).

Next, in the step S4, a cathode layer 122 is formed on the organic light-emitting layer 114. In the embodiment, the cathode layer 122 may include a stack of a metal layer 117, an organic buffer layer 119, and a transparent conductive layer 121. The metal layer 117 has a thickness of about 40 Å and may include magnesium (Mg), sliver (Ag), or an alloy thereof. Moreover, the metal layer 117 may be formed by evaporation.

The organic buffer layer 119, such as HAT-CN, has a thickness in a range of in a range of 10 Å to 500 Å, and is preferable in a range of 50 Å to 300 Å. Moreover, the organic buffer layer 119 may be formed by evaporation. For example, in the evaporation process, the process temperature is in a range of 200° C. to 450° C., and the deposition rate is in a range of 0.1 Å/sec to 10 Å/sec. In another embodiment, the organic buffer layer 119 may further include another organic material, such as BeBq₂, and be formed by co-evaporation.

The transparent conductive layer 121, such as ITO or IZO, has a thickness of about 1000 Å, and may be formed by a sputtering process or evaporation process. For example, the transparent conductive layer 121 is formed by a sputtering process with a process pressure in a range of 0.05 Pa to 6 Pa and a process power of 1 KW to 10 KW.

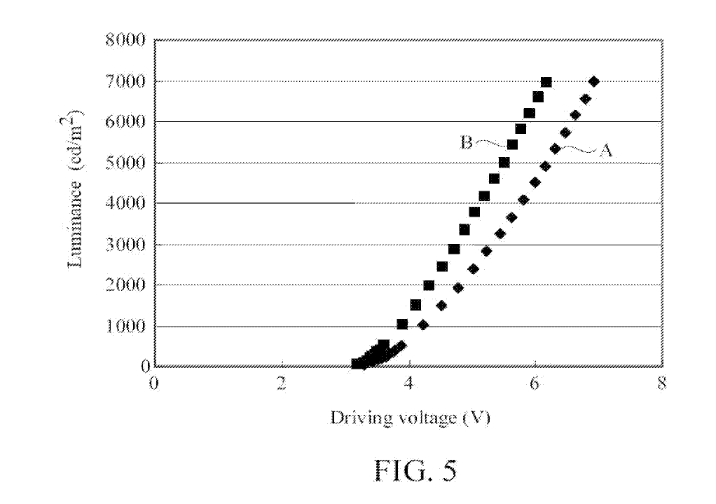

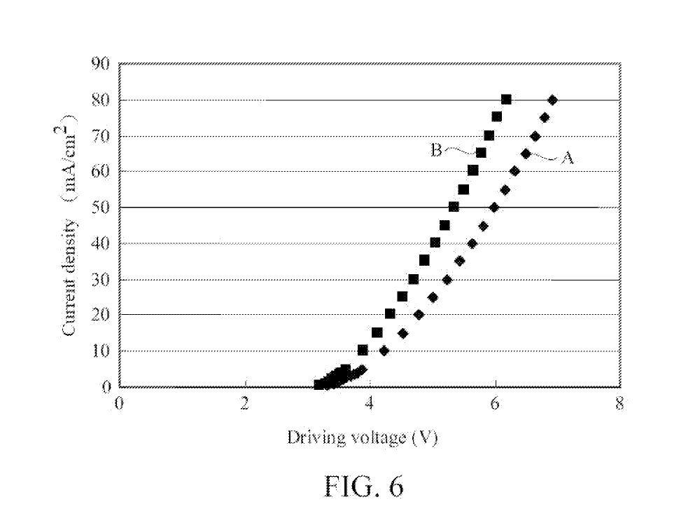

Referring to FIGS. 4 to 6, FIG. 4 is a diagram showing a relationship between efficiency (cd/A) and current density (mA/cm²), FIG. 5 is a diagram showing a relationship between luminance (cd/m²) and driving voltage (V), and FIG. 6 is a diagram showing a relationship between current density (mA/cm²) and driving voltage (V). In FIGS. 4 to 6, the curve A represents a case of the OLED 200 where the organic buffer layer 119 has a thickness of zero (i.e., without the organic buffer layer 119), and the curve B represents a case of the OLED 200 where the organic buffer layer 119 has a thickness of 100 Å. As shown in FIG. 4, the existence of the organic buffer layer 119 does not reduce the efficiency of the OLED 200. Moreover, as shown in FIG. 5, the case of the OLED 200 with the organic buffer layer 119 has a higher luminance than that of the case of the OLED 200 without the organic buffer layer 119, as both are operated under the same driving voltage. Additionally, as shown in FIG. 6, the case of the OLED 200 with the organic buffer layer 119 has a lower driving voltage than that in the case of the OLED 200 without the organic buffer layer 119, as both are operated under the same current density.

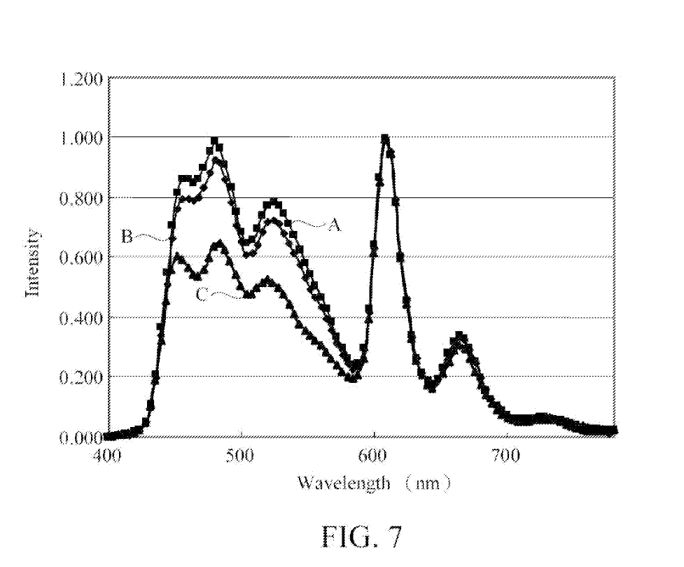

FIG. 7 is a spectrum diagram of the OLED 200 according to the invention, in which the curve A represents a case of the OLED 200 where the organic buffer layer 119 has a thickness of zero, the curve B represents a case of the OLED 200 where the organic buffer layer 119 has a thickness of 100 Å, and the curve C represents a case of the OLED 200 where the organic buffer layer 119 has a thickness of 300 Å. As shown in FIG. 7, the spectrum of the OLED 200 is varied with increased thickness of the organic buffer layer 119. Accordingly, the light color of the OLED 200 can be adjusted by varying the thickness of the organic buffer layer 119.

According to the foregoing embodiments, since the use of the organic buffer layer 119 can protect the organic light-emitting layer 114 thereunder from being damaged and prevent the metal layer 117 thereunder from being oxidized during the formation of the transparent conductive layer 121, the light-emitting characteristics of the OLED 200 can be maintained. Moreover, since the organic buffer layer 119 can further enhance the carrier injection ability, the luminance of the OLED 200 can be increased and the driving voltage thereof can also be reduced. Additionally, since the organic buffer layer 119 can increase the step coverage of the transparent conductive layer 121, the reliability of the OLED 200 can be increased.

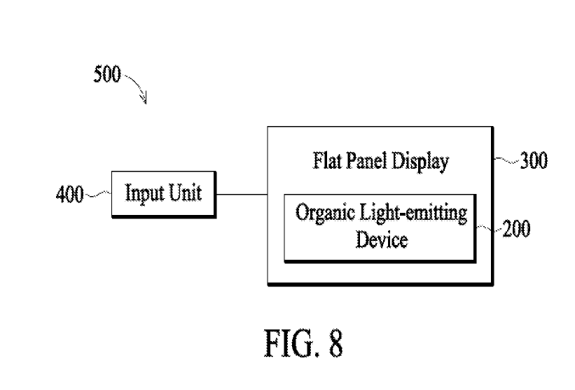

FIG. 8 schematically shows another embodiment of a system for displaying images which, in this case, is implemented as a flat panel display (FPD) 300 or an electronic device 500 such as a laptop computer, a mobile phone, a digital camera, a personal digital assistant (PDA), a desktop computer, a television, a car display or a portable DVD player. The FPD 300 may include the described organic light-emitting device (OLED) 200, and the FPD 300 may be an OLED panel. As shown in FIG. 8, the FPD 300 includes the OLED 200 as shown in FIG. 2. In some embodiments, the FPD 300 can be incorporated into the electronic device 500. As shown in FIG. 8, the electronic device 500 includes the FPD 300 and an input unit 400. Moreover, the input unit 400 is coupled to the FPD 300 and is operative to provide input signals (e.g. image signals) to the FPD 300 to generate images.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A system for displaying images, comprising:
an organic light-emitting device comprising:
an anode layer disposed on a substrate;
an organic light-emitting layer disposed on the anode layer; and
a cathode layer disposed on the organic light-emitting layer, comprising:
a metal layer contacting the organic light-emitting layer;
a transparent conductive layer disposed on the metal layer; and
an organic buffer layer disposed between the metal layer and the transparent conductive layer, wherein the organic buffer layer has a carrier mobility in a range of 10⁻³ cm²/(V·s) to 10⁻⁵ cm²/(V·s).

2. The system of claim 1, wherein the organic buffer layer has a glass transition temperature not less than 110° C.

3. The system of claim 1, wherein the organic buffer layer has a lowest unoccupied molecular orbital (LUMO) in a range of 3.5 eV to 6.5 eV.

4. The system of claim 1, wherein the organic buffer layer has a transmittance of not less than 70%.

5. The system of claim 1, wherein the organic buffer layer has a reflectivity in a range of 1.5 to 2.0.

6. The system of claim 1, wherein the organic buffer layer comprises at least two organic materials.

7. The system of claim 1, wherein the organic buffer layer comprises hexaazatriphenylene hexacarbonitrile (HAT-CN).

8. The system of claim 1, wherein the organic buffer layer has a thickness in a range of 10 Å to 500 Å.

9. The system of claim 1, wherein the organic light-emitting layer comprises a stack of a hole injecting layer (HIL), a hole transporting layer (HTL), an electroluminescent layer (EML), an electron transporting layer (ETL), and an electron injecting layer (EIL).

10. The system as claimed in claim 1, further comprising:
a flat panel display comprising the organic light-emitting device; and
an input unit coupled to the flat panel display and operative to provide input singles to the flat panel display, such that the flat panel display displays images.

11. The system of claim 10, wherein the system is an electronic device comprising the flat panel display.

12. The system of claim 11, wherein the electronic device is a laptop computer, a mobile phone, a digital camera, a personal digital assistant, a desktop computer, a television, a car display or a portable DVD player.
